(19) United States
(12) Patent Application Publication
(10) Pub. No.: US 2012/0063072 A1
(43) Pub. Date: Mar. 15, 2012

(54) TERMINAL DEVICE AND TILTING MECHANISM

(75) Inventors: Junichi MURAKOSO, Kawasaki (JP); Tomoyuki Nagamine, Kawasaki (JP)

(73) Assignee: FUJITSU LIMITED, Kawasaki-shi (JP)

(21) Appl. No.: 13/158,366

(22) Filed: Jun. 10, 2011

(30) Foreign Application Priority Data
Sep. 13, 2010 (JP) 2010-203917

(51) Int. Cl. H05K 5/02; E05D 7/04

(52) U.S. Cl. 361/679.01; 16/242

(57) ABSTRACT

A tilting hinge is disposed on a fixed housing and includes a rotating shaft, a bearing, and a movable piece. The rotating shaft includes a protrusion. Meanwhile, a lower half of the rotating shaft has a spiral curved surface. The bearing is provided with a spiral groove following the lower half of the rotating shaft, and the rotating shaft is biased toward the groove on the bearing by use of presser bar springs. Tilting of the movable housing causes the protrusion on the rotating shaft to slide on a surface of the groove on the bearing, and a rotation center of the rotating shaft to move upward.

### CROSS-REFERENCE TO RELATED APPLICATIONS

This application is based upon and claims and the benefit of priority of the prior Japanese Patent Application No. 2010-203917, filed Sep. 13, 2010, the entire contents of which are incorporated herein by reference.

### FIELD

The embodiments discussed herein relate to a terminal device and a tilting mechanism.

### BACKGROUND

Multifunctional mobile telephones as typified by smartphones have been widely used in recent years. Many of these multifunctional mobile telephones include a mechanism to allow a screen to slide. A terminal device such as a mobile telephone including the mechanism to allow the screen to slide will be hereinafter referred to as a slide-type terminal device. The slide-type terminal device includes a housing (hereinafter referred to as a fixed housing) provided with input keys (numerical keys, QWERTY keys, or the like) and a housing (hereinafter referred to as a movable housing) provided with a display device such as a liquid crystal panel as well as a slide rail. Moreover, a rail holder engaged with the slide rail and configured to slidably support the movable housing is fitted on the fixed housing.

Many of the multifunctional mobile telephones are capable of displaying moving images distributed via television broadcast or the Internet, moving images stored in a memory, and the like. A common slide-type terminal device is merely configured such that the movable housing is slidable relative to the fixed housing. Accordingly, the terminal device simply put on a desk has poor visibility because a user may be forced to look at the screen obliquely. Hence there has been proposed a terminal device including a combination of a sliding mechanism with a tilting mechanism (a mechanism configured to tilt the movable housing).

Patent Document 1: Japanese Laid-open Patent Publication No. 2007-74411

However, the conventional terminal device provided with the sliding mechanism and the tilting mechanism only has a small tilting angle which is at most 30°.

### SUMMARY

According to one aspect, a terminal device includes: a fixed housing provided with an input device; a movable housing provided with a display device and disposed to overlap the fixed housing; and a tilting hinge configured to tiltably connect the movable housing to the movable housing. In the terminal device the tilting hinge includes: a rotating shaft; a bearing configured to rotatably support the rotating shaft; a movable piece having one end side connected to the rotating shaft and another end side connected to the movable housing; and a rotation center moving unit configured to move a rotation center of the rotating shaft toward the movable housing along with rotation of the rotating shaft.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A to FIG. 1C are schematic diagrams illustrating an example of a terminal device (a mobile telephone) having a sliding mechanism and a tilting mechanism;

FIG. 2 is a perspective view of a terminal device according to an embodiment;

FIG. 3 is a side view of the terminal device of the embodiment in a closed state;

FIG. 4 is a view of the terminal device viewed in a direction indicated with an arrow B in FIG. 2;

FIG. 5 is a schematic cross-sectional view of a tilting mechanism;

FIG. 6 is a schematic perspective view of a tilting hinge;

FIG. 7A and FIG. 7B are schematic diagrams illustrating an action to open the terminal device;

FIG. 8 is a schematic diagram illustrating an action of the tilting hinge when the movable housing is tilted;

FIG. 9 is a perspective view illustrating a terminal device of a first modification;

FIG. 10A to FIG. 10C are perspective views illustrating a terminal device of a second modification; and

FIG. 11 is a schematic cross-sectional view of a tilting mechanism of a terminal device of a third modification.

### DESCRIPTION OF EMBODIMENT

Preludes for facilitating understanding of embodiments will be explained below prior to description of the embodiments.

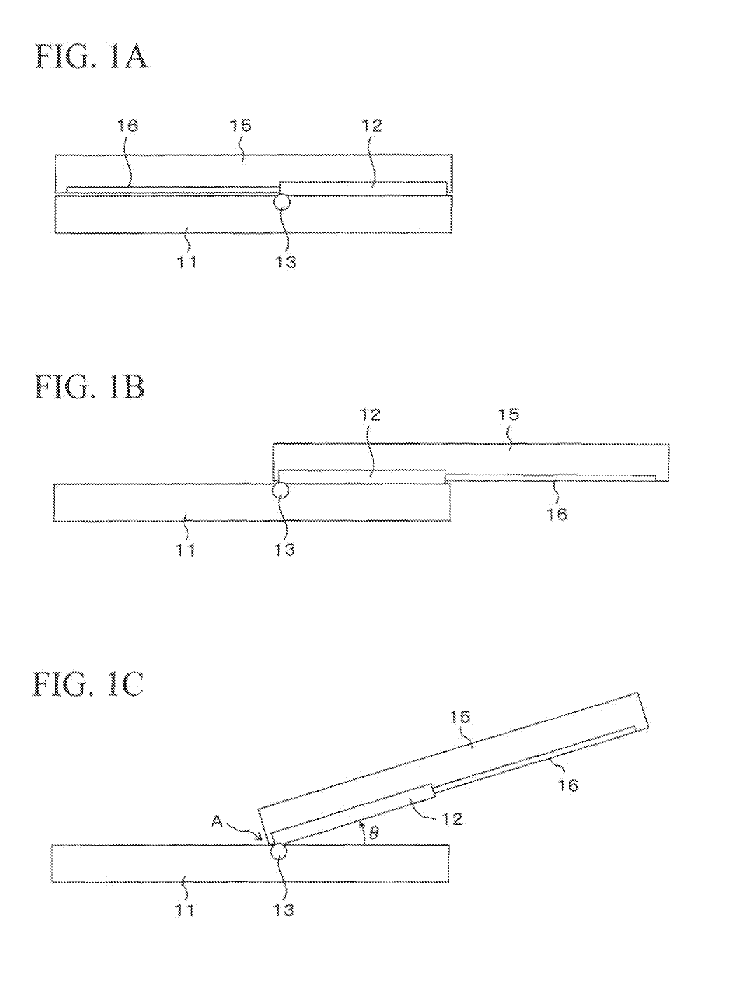

FIG. 1A to FIG. 1C are schematic diagrams illustrating an example of a terminal device (a mobile telephone) having a sliding mechanism and a tilting mechanism.

A fixed housing 11 is provided with numerical keys and other input keys while a movable housing 15 is provided with a display device such as a liquid crystal panel and a slide rail 16.

As illustrated in FIG. 1A, a tilting hinge 13 is placed on an upper surface side of the fixed housing 11, and a rail holder 12 is fitted on a movable piece side of this tilting hinge 13. This rail holder 12 is rotatable within a predetermined angle range around a central axis of the tilting hinge 13 as a center of rotation.

The rail holder 12 is engaged with the slide rail 16 so as to slidably support the movable housing 15. FIG. 1B illustrates a state where the movable housing 15 is allowed to slide horizontally on the upper surface of the fixed housing 11 to an end of the slide rail 16. The movable housing 15 sliding to the end of the slide rail 16 may be tilted (be inclined) pivotally around the central axis of the tilting hinge 13 as the center of rotation as illustrated in FIG. 1C. The state illustrated in FIG. 1A will be hereinafter referred to as a closed state while the state illustrated in FIG. 1B or FIG. 1C will be hereinafter referred to as an open state.

Incidentally, the tilting hinge 13 is disposed in a position not protruding from the upper surface of the fixed housing 11 so as not to stand in the way of the sliding movable housing 15. For this reason, a clearance between the movable housing 15 and the fixed housing 11 is small, and an end portion (a portion indicated with an arrow A in the drawing: hereinafter also referred to as a rear end) of the movable housing 15 abuts on the fixed housing as illustrated in FIG. 1C when the movable housing 11 is tilted. As a consequence a tilt angle θ is limited to about 30° at the maximum in the case of the above-described terminal device.

The clearance between the rear end of the movable housing 15 and the fixed housing 11 is increased by locating the rotation center of the tilting hinge 13 above the upper surface of the fixed housing 11, whereby it may be possible to increase the tilt angle. However, a large clearance is formed between the fixed housing 11 and the movable housing 15 in this case even when the terminal device is closed. Accordingly, this configuration is not favorable in terms of design.

It is also conceivable that the rear end of the movable housing 15 is cut out into a curved surface so as to avoid the abutting of the tilted movable housing 15 on the fixed housing 11. Nevertheless, a clearance is similarly formed between the fixed housing 11 and the rear end of the movable housing 15 when the terminal device is closed. Hence it is difficult to adopt this configuration in terms of design.

Now an embodiment will be described below with reference to the accompanying drawings.

### Embodiment

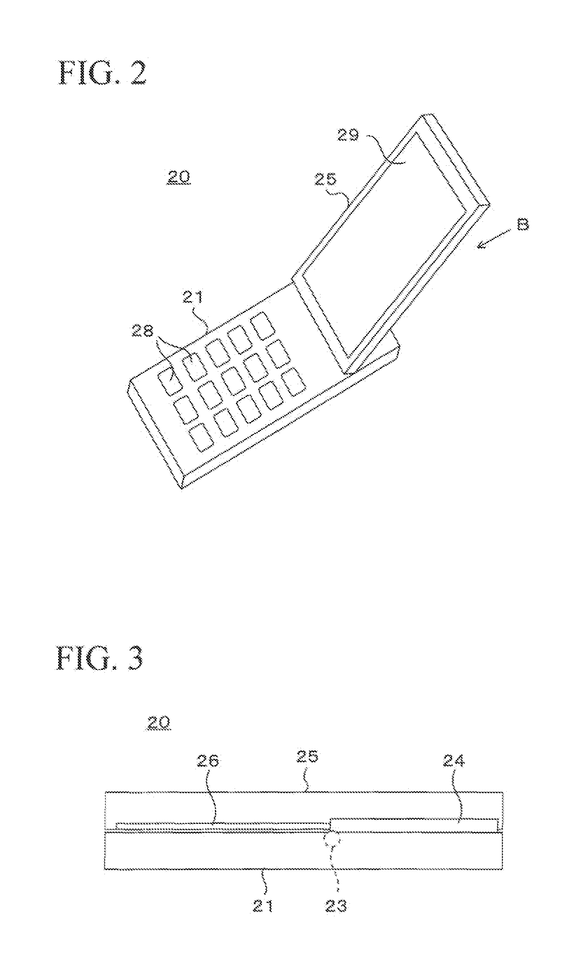

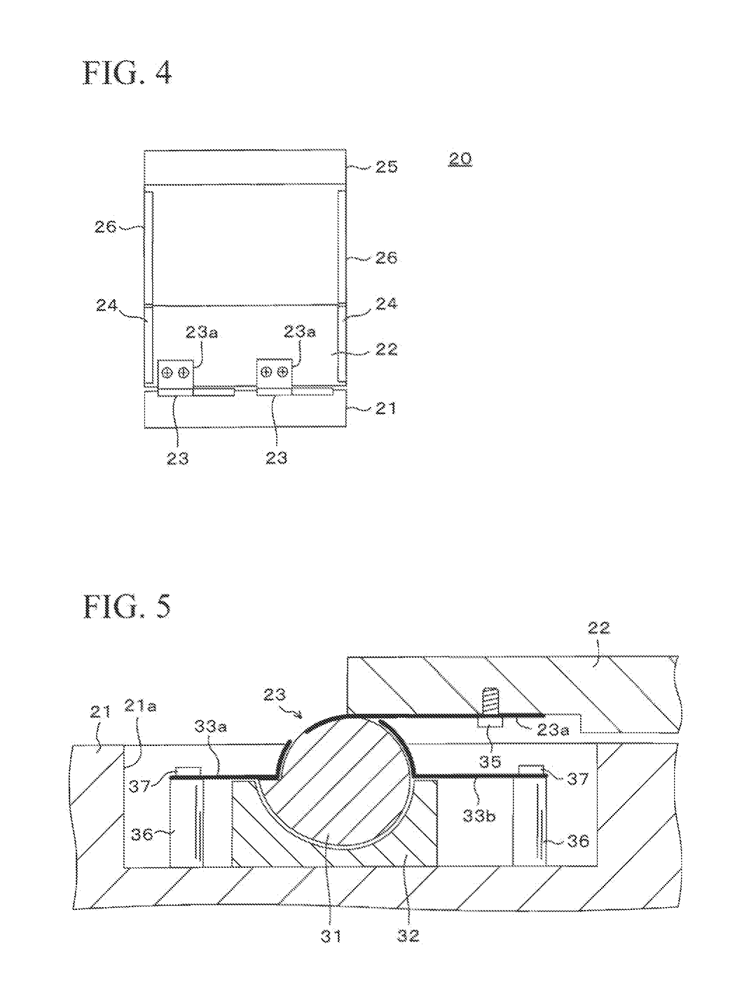

FIG. 2 is a perspective view of a terminal device according to an embodiment. FIG. 2 illustrates a state of the terminal device in the opening state. Meanwhile, FIG. 3 is a side view of the terminal device in the closed state. Further, FIG. 4 is a diagram of the terminal device viewed from a direction indicated with an arrow B in FIG. 2. Although this embodiment describes a case where the terminal device is a mobile telephone, the techniques to be described below are also applicable to a PDA (persona digital assistant) or other electronic devices.

A terminal device 20 according to the embodiment includes a fixed housing 21 provided with an input device 28 (numerical keys or other input keys), and a movable housing 25 provided with a display device (such as a liquid crystal panel) 29 capable of displaying characters and images. Slide rails (grooves) 26 which extend in a longitudinal direction of the movable housing 25 are provided on both sides in a width direction of the movable housing 25.

Meanwhile, tilting hinges 23 are disposed on an upper surface side of the fixed housing 21. As illustrated in FIG. 4, a tilting plate 22 is fitted on movable pieces 23a of the tilting hinges 23, and the tilting plate 22 is tilted at an angle corresponding to a rotation angle of the movable pieces 23a.

Rail holders 24 are provided on both sides in a width direction of the tilting plate 22. These rail holders 24 are engaged with the slide rails 26 so as to slidably support the movable housing 25.

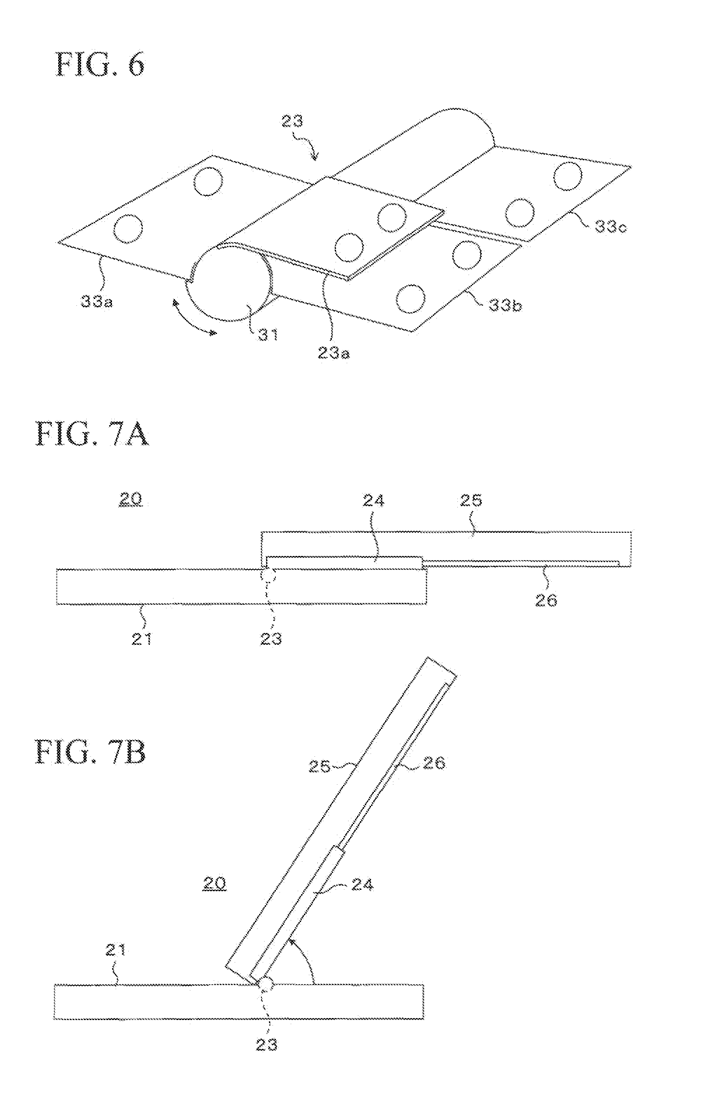

FIG. 5 is a schematic cross-sectional view of a tilting mechanism, namely, the tilting hinge 23 and peripheral portions thereof. Meanwhile, FIG. 6 is a schematic perspective view of the tilting hinge 23. Note that both of FIG. 5 and FIG. 6 illustrate states of parts of the tilting hinge 23 in the closed state of the terminal device 20.

The tilting hinge 23 of the terminal device 20 according to this embodiment includes a rotating shaft 31, a bearing 32, the movable piece 23a, and presser bar springs (leaf springs) 33a, 33b, and 33c. Meanwhile, the tilting hinge 23 is disposed inside a recessed portion 21a provided in the upper surface side of the fixed housing 21.

The rotating shaft 31 is a rod-shaped member, of which an upper half has a semicircular curved surface and a lower half has a spiral (such as a logarithmic spiral) curved surface in the closed state of the terminal device 20 as illustrated in FIG. 5. Moreover, the upper curved surface and the lower curved surface of the rotating shaft 31 are smoothly connected on the right side as illustrated in FIG. 5 while a step is formed between the upper curved surface and the lower curved surface on the left side. This step portion will be hereinafter referred to as a protrusion.

In this embodiment, a curvature radius of the curved surface of the upper half (the semicircular portion) of the rotating shaft 31 is set to 1.5 mm and the step (a height of the protrusion) is set to 0.5 mm. The rotating shaft 31 is made of metal or hard resin, for example.

The movable piece 23a is connected to a peak of the rotating shaft 31 and is disposed to extend in a horizontal direction (toward the right in FIG. 5). The tilting plate 22 is a plate-like member made of metal, resin, or the like, and is fitted to the movable piece 23a with a screw 35.

The bearing 32 is provided with a groove having a spiral curved surface following the curved surface of the lower side of the rotating shaft 31, and is configured to rotatably support the rotating shaft 31 by using this groove portion. This bearing 32 is made of hard resin having a fine sliding performance, for example.

The presser bar springs 33a and 33b are disposed at positions to sandwich the rotating shaft from both sides, and curved portions on tips thereof are configured to contact the rotating shaft 31 and to bias the rotating shaft 31 so as to push the rotating shaft 31 into the groove on the bearing 32.

Here, as illustrated in FIG. 5, the movable piece 23a is passed through a clearance between the tips of the presser bar springs 33a and 33b and is connected to the tilting plate 22. Meanwhile, in FIG. 5 (in the closed state), the movable piece 23a is placed parallel to the upper surface of the fixed housing 21. However, the angle between the movable piece 23a and the upper surface of the fixed housing 21 is changed by rotation of the rotating shaft 31.

As illustrated in FIG. 6, the presser bar spring 33c is disposed adjacent to the presser bar spring 33b. A tip of this presser bar spring 33c is bent to wrap the rotating shaft 31 and is configured to generate a frictional force to retain a tilted state when the movable housing 25 is tilted. Note that the protrusion is not provided at a portion of the rotating shaft 31 wrapped with the tip of the presser bar spring 33c in this embodiment. Specifically, the portion of the rotating shaft 31 corresponding to the presser bar spring 33c is formed into a cylindrical shape.

Portions of these presser bar springs 33a, 33b, and 33c on the opposite side of the rotating shaft 31 are respectively fixed to a peak of a bar member 36 provided inside the recessed portion 21a by use of screws 37. These presser bar springs 33a, 33b, and 33c prevent the rotating shaft 31 from coming off the groove on the bearing 32.

Now, an action to open the terminal device will be described below. When the terminal device 20 is in the closed state, the movable housing 25 is stacked on the fixed housing 21 as illustrated in FIG. 3, and the terminal device 20 has a substantially rectangular parallelepiped shape as a whole.

For opening the terminal device 20, the movable housing 25 is caused to slide to the ends of the slide rails 26 as illustrated in FIG. 7A. By causing the movable housing 25 to slide as described above, the input device on the upper surface of the fixed housing 21 is exposed so as to allow input by key operation. Although it is possible to use the terminal device 20 in this state, the movable housing 25 is assumed to be tilted in this case.

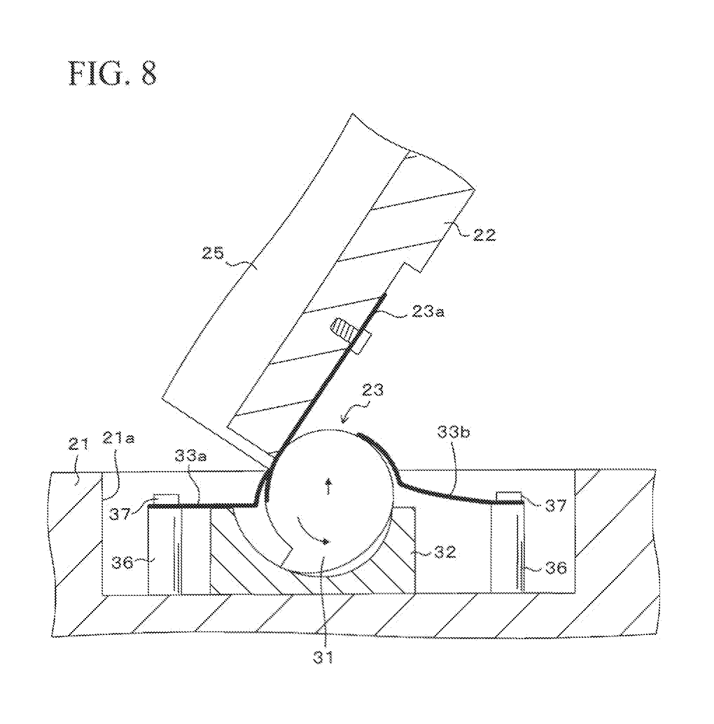

FIG. 8 is a schematic diagram illustrating an action of the tilting hinge 23 when the movable housing 25 is tilted. To tilt the movable housing 25, the movable housing 25 is caused to slide to the ends of the slide rails 26 as illustrated in FIG. 7A and is then tilted by pushing the tip of the movable housing 25 upward. Here, the tilting direction of the movable housing 25 is assumed to be counterclockwise as illustrated in FIG. 7B. Accordingly, the rotating shaft 31 is rotated in the circumferential direction (counterclockwise) as illustrated in FIG. 8.

Meanwhile, the groove on the bearing 32 is formed into the spiral curved surface which is coiled in the opposite direction to the tilting direction of the movable housing 25 (clockwise from the center outward). For this reason, while the protrusion slides along the curved surface of the groove on the bearing 32 with the rotation of the rotating shaft 31, the protrusion pushes a rotation center of the rotating shaft 31 upward as illustrated in FIG. 8.

In this way, the clearance between the rear end of the movable housing 25 and the upper surface of the fixed housing 21 becomes larger than the case of locating the rotation center of the rotating shaft 31 in the stationary position. Thus it may be possible to tilt (incline) the movable housing 25 at a larger angle as illustrated in FIG. 7B. For example, if the curvature radius of the rotating shaft 31 is equal to 1.5 mm and the height of the protrusion is equal to 0.5 mm as described previously, then it may be possible to incline the movable housing 25 at about 60° at the maximum (about +27° as compared to the case of locating the rotation center in the stationary position).

Here, the tilted movable housing 25 is retained at the tilted angle by the frictional force acting between the presser bar spring 33c and the rotating shaft 31.

The terminal device 20 according to this embodiment may achieve the large tilt angle of the movable housing 25. Accordingly, the terminal device 20 may achieve fine visibility by allowing a user to look at characters, images or moving images displayed on the screen squarely when the terminal device 20 is placed on a desk. Meanwhile, the terminal device 20 has excellent design in the closed state because of the small clearance between the fixed housing 21 and the movable housing 25 as illustrated in FIG. 3.

### First Modification

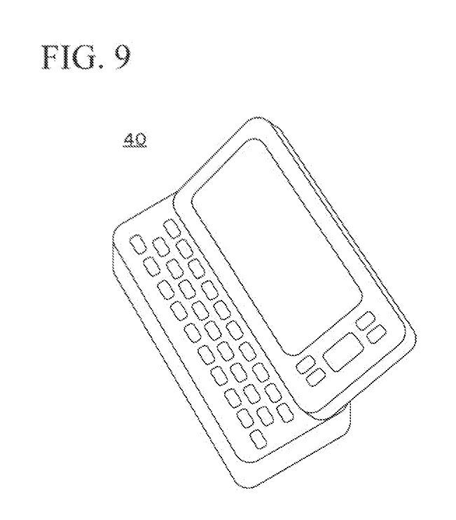

Although the embodiment describes the case of attaching the tilting mechanism to the terminal device of so-called a vertical sliding type which allows the movable housing 25 to move in a longitudinal direction thereof, the embodiment is also applicable to a terminal device of a lateral sliding type as illustrated in FIG. 9.

Smartphones are often configured such that keyboards (QWERTY keys) are exposed by causing a movable housing to slide in a lateral direction (a direction orthogonal to a longitudinal direction). FIG. 9 is a perspective view illustrating an example of the terminal device of the lateral sliding type having the sliding mechanism and the tilting mechanism described in the embodiment.

A terminal device 40 illustrated in FIG. 9 has a large tilting angle so that a user may input characters and the like with the keyboards while adjusting a screen at an appropriate angle. Accordingly, the terminal device 40 is improved in usability in comparison with a terminal device of the lateral sliding type without the tilting mechanism.

### Second Modification

Mobile telephone of a folding type often include a swinging mechanism configured to change a screen into a landscape screen by turning the screen by 90° for watching TV broadcast (One-Seg broadcast), for example.

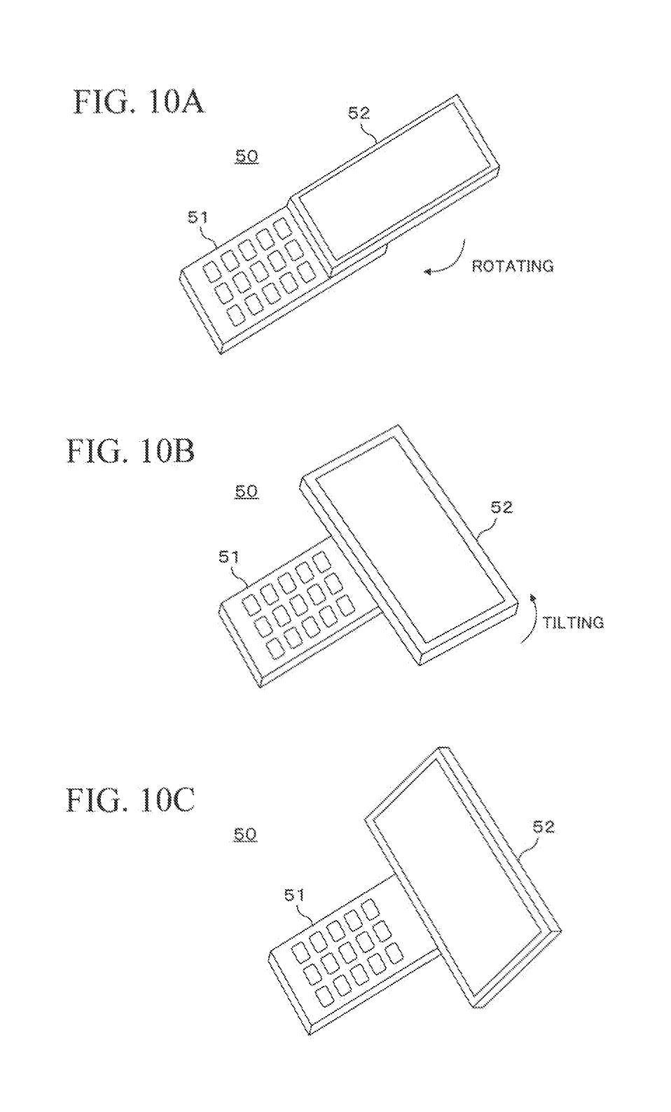

FIG. 10A to FIG. 10C illustrate an example of a terminal device 50 further including a swinging mechanism in addition to the sliding mechanism and the tilting mechanism described in the embodiment. Specifically, the swinging mechanism is provided between a tilting plate and a movable housing. A movable housing 52 is caused to slide relative to a fixed housing 51 to an end of a slide rail as illustrated in FIG. 10A. Then, the movable housing is turned by 90°. Thereafter, the movable housing 52 is tilted to a desired angle as illustrated in FIG. 10B and FIG. 10C.

The above-described terminal device 50 may take three kinds of the open state as illustrated in FIG. 10A to FIG. 10C in addition to the closed state. Hence it may be possible to use the terminal device in the most suitable state depending on the situation. Here, since the swinging mechanism is publicly known, detailed description of the swinging mechanism will be omitted herein.

### Third Modification

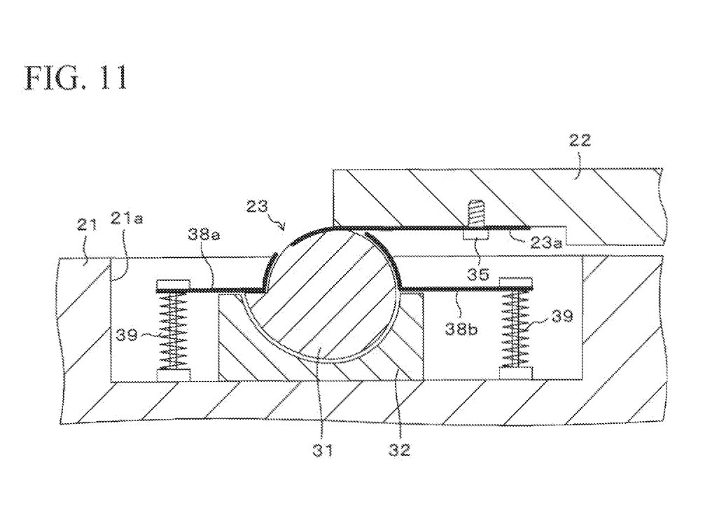

In the above-described embodiment, the rotating shaft 31 is biased toward the groove on the bearing by use of the leaf springs (the presser bar springs 33a, and 33b). Instead, it may be also possible to bias the rotating shaft 31 toward the groove on the bearing 32 by use of pressing members 38a and 38b as well as coil springs 39 as illustrated in FIG. 11. Alternatively, it may be also possible to bias the rotating shaft 31 toward the groove on the bearing 32 by use of torsion bars and other elastic bodies.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A terminal device comprising:
a fixed housing provided with an input device;
a movable housing provided with a display device and disposed to overlap the fixed housing; and
a tilting hinge configured to tiltably connect the movable housing to the fixed housing, the tilting hinge comprising:
a rotating shaft;
a bearing configured to rotatably support the rotating shaft;
a movable piece having one end side connected to the rotating shaft and another end side connected to the movable housing; and
a rotation center moving unit configured to move a rotation center of the rotating shaft toward the movable housing along with rotation of the rotating shaft.

2. The terminal device according to claim 1, wherein
the rotation center moving unit is a protrusion provided on the rotating shaft.

3. The terminal device according to claim 2, wherein
a surface of the bearing contacting the rotating shaft is a spiral curved surface being coiled in an opposite direction to a tilting direction of the movable housing.

4. The terminal device according to claim 1, further comprising:
a slide rail provided on the movable housing;
a slide rail holder engaged with the slide rail and configured to support the movable housing in such a manner that the movable housing is slidable in a direction of extension of the slide rail; and
a tilting plate configured to connect the movable piece to the slide rail holder.

5. The terminal device according to claim 1, further comprising:
a swinging mechanism configured to turn the movable housing by 90° on a plane parallel to a surface of the display device.

6. The terminal device according to claim 3, wherein
a groove having a shape following a circumferential surface of the rotating shaft is provided on the bearing.

7. The terminal device according to claim 3, wherein
the rotating shaft is biased toward the bearing by an elastic body.

8. The terminal device according to claim 1, wherein
the tilting hinge is disposed inside a recessed portion provided in the fixed housing.

9. A tilting mechanism in which a second member is tiltably connected to a first member, the tilting mechanism comprising:
a rotating shaft;
a bearing provided on the first member and configured to rotatably support the rotating shaft;
a movable piece having one end side connected to the rotating shaft and another end side connected to the second member; and
a rotation center moving unit configured to move a rotation center of the rotating shaft toward the second member along with rotation of the rotating shaft.

10. The tilting mechanism according to claim 9, wherein
the rotating shaft moving unit is a protrusion provided on the rotating shaft.

11. The tilting mechanism according to claim 10, wherein
a surface of the bearing contacting the rotating shaft is a spiral curved surface being coiled in an opposite direction to a tilting direction of the second member.

12. The tilting mechanism according to claim 11, wherein
a groove having a shape following a circumferential surface of the rotating shaft is formed on the bearing.
